(19) United States
(12) Patent Application Publication
(10) Pub. No.: US 2011/0169165 A1
(43) Pub. Date: Jul. 14, 2011

(54) SEMICONDUCTOR DEVICE

(75) Inventor: KAZUYOSHI AJIRO, KANAGAWA (JP)

(73) Assignee: RENESAS ELECTRONICS CORPORATION, KANAGAWA (JP)

(21) Appl. No.: 13/004,992

(22) Filed: Jan. 12, 2011

(30) Foreign Application Priority Data
Jan. 14, 2010 (JP) 2010-005912

(51) Int. Cl. H01L 23/48

(52) U.S. Cl. 257/741; 257/E23.01

(57) ABSTRACT

A semiconductor device according to the present invention includes a substrate, an IC chip that is fixed over the substrate, a conductor that is disposed over a surface of the substrate, a solder resist that covers the surface of the substrate and the conductor and includes an opening that exposes the conductor in a section corresponding to a fixed surface of the IC chip, and an adhesive that contacts an exposed part of the conductor, in which the exposed part is made by the opening.

### INCORPORATION BY REFERENCE

This application is based upon and claims the benefit of priority from Japanese patent application No. 2010-005912, filed on Jan. 14, 2010, the disclosure of which is incorporated herein in its entirety by reference.

### BACKGROUND

1. Field of the Invention

The present invention relates to a semiconductor device in which an IC (Integrated Circuit) chip is mounted to a printed circuit board, and particularly to a technique for eliminating unnecessary elements such as heat.

2. Description of Related Art

Currently, in various electric appliances, an IC chip which provides a desired function has been used in states of being fixed over a printed circuit board. As the IC chip generates heat, electric noise, or the like during the operation, it is required to include, for example, a heat dissipation function and a noise suppression function in the semiconductor device with the above configuration.

FIG. 5 exemplifies a configuration of a semiconductor device 101 according to a prior art. An IC chip 103 is fixed over a printed circuit board 102 of the semiconductor device 101 with an adhesive 105 interposed therebetween, such as Ag paste. A top surface of the printed circuit board 102 is covered with a package 104, such as resin. A conductor 111 as wiring is disposed over the surface of a substrate 110 of the printed circuit board 102. The substrate 110 and the conductor 111 are covered with a solder resist 112 as an insulating layer. The conductor 111 extends from the surface where the IC chip 103 is fixed to an opposite surface with a plurality of via openings 115 penetrating the substrate 110 interposed therebetween, and is connected to solder balls 113, which are connection points with an external device. The IC chip 103 is composed of a substrate 120, which is formed of a semiconductor or the like, and a functional device group 121 that provides a predetermined function. The functional device group 121 is fixed over the substrate 120. The printed circuit board 102 and the IC chip 103 are connected in order to enable transmission and reception of an electric signal via bonding wires 106. The solder resist 112 covers the conductor 110 in all the part except the connection points such as bonding points 114 of the bonding wires 106 on the surface where the IC chip 103 is fixed.

The configuration disclosed by Japanese Unexamined Patent Application Publication No. 8-172141 includes a VSS plane in which a three-layer BGA (Ball Grid Array) package is disposed between upper and lower traces, a VSS trace disposed over the upper and lower surfaces of a peripheral region, and via openings electrically and thermally connecting the VSS plane and the VSS traces of the upper and lower surfaces. Then the VSS plane placed to the inner layer composes a low impedance current path.

In the configuration disclosed in Japanese Unexamined Patent Application Publication No. 4-42989, inside an insulating substrate, two layers, which are an upper metal layer for heat dissipation and a lower metal layer for heat dissipation, are spaced from each other, a heat dissipation metal layer is disposed over a back side of the insulating substrate. The upper metal layer is connected to a metal plating layer in a recess. The upper and lower metal layers are connected by an inner via hole which is metal-plated by a layer. Then heat dissipation and moisture resistance can be improved without using a heat sink.

In the configuration disclosed in Japanese Unexamined Patent Application Publication No. 2002-313980, an IC chip is mounted across a first conductor and a second conductor of a printed circuit board, and both of the conductors are grounded. This is expected to prevent a failure generated due to mixed environment of current from analog and digital circuits.

### SUMMARY

In the semiconductor device 101 shown in FIG. 5, the adhesives 105 exists between the solder resist 112 and the substrate 120. The general solder resist 112 has characteristics in which thermal conductivity and electrical conductivity is low. The present inventor has found following problems that in the semiconductor device 101, an elimination element 130 such as heat and electric noise generated by the operation of the functional device unit 121 is blocked by the solder resist 112, and tends to be accumulated in the substrate 120. Accordingly, in a device having a similar configuration as the above semiconductor device 101, there is room for improvement in terms of heat dissipation and noise suppression performance.

The configurations disclosed in Japanese Unexamined Patent Application Publication Nos. 8-172141 and 4-42989 adopt a multilayer configuration in order to improve heat dissipation property. Accordingly, cost increase due to an increase in the number of the manufacturing process and the number of parts will be a problem. Moreover, in the configuration disclosed in Japanese Unexamined Patent Application Publication No. 2002-313980, the conductors for analog and digital are separately prepared, and the conductors extend outside the chip edge. According to such configuration, a wiring crack may occur by stress generated in the package due to thermal stress, and there is more room for improvement in terms of the heat dissipation property.

A first exemplary aspect of the present invention is a semiconductor device that includes a substrate, an IC chip that is fixed over the substrate, a conductor that is disposed over a surface of the substrate, a solder resist that covers the surface of the substrate and the conductor and includes an opening that exposes the conductor in a section corresponding to a fixed surface of the IC chip, and an adhesive that contacts an exposed part of the conductor, in which the exposed part is made by the opening.

According to the abovementioned aspect, the conductor of the part corresponding to the fixed surface of the IC chip among the coated range of the solder resist is exposed by the opening formed in the solder resist. Then, the adhesive directly contacts the IC chip and the conductor through the opening. In other words, the thermal conductivity from the IC chip to the conductor will be favorable as the solder resist does not exist therebetween. Then the heat generated in the IC chip is efficiently eliminated outside via the adhesive and the conductor. Moreover, by selecting material used for the substrate of the IC chip and the adhesive, it is possible to thermally and also electrically connect from the IC chip to the conductor. According to such a configuration, electric noise or the like generated in the IC chip can also be eliminated.

According to the present invention, it is possible to efficiently eliminate unnecessary elements such as heat generated by the operation of the IC chip without increasing the cost.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a cross-sectional diagram showing a configuration of a semiconductor device according to a first exemplary embodiment of the present invention;

FIG. 2 is a top view showing a state before mounting an IC chip of a printed circuit board and an example of a shape of an opening according to the first exemplary embodiment;

FIG. 3 is a top view showing a state before mounting an IC chip of a printed circuit board and an example of a shape of an opening according to the first exemplary embodiment; and

FIG. 4 schematically illustrates a cross-sectional structure when the IC chip is mounted to a fixed part in the first exemplary embodiment; and

FIG. 5 is a cross-sectional diagram showing a configuration of a semiconductor device according to a prior art.

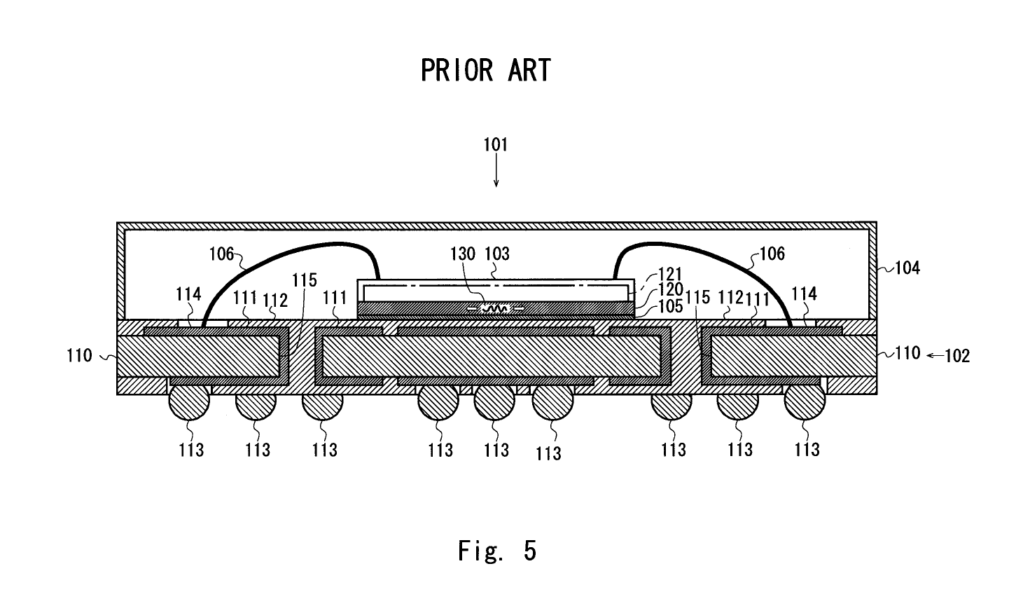

### DETAILED DESCRIPTION OF THE EXEMPLARY EMBODIMENT

### First Exemplary Embodiment

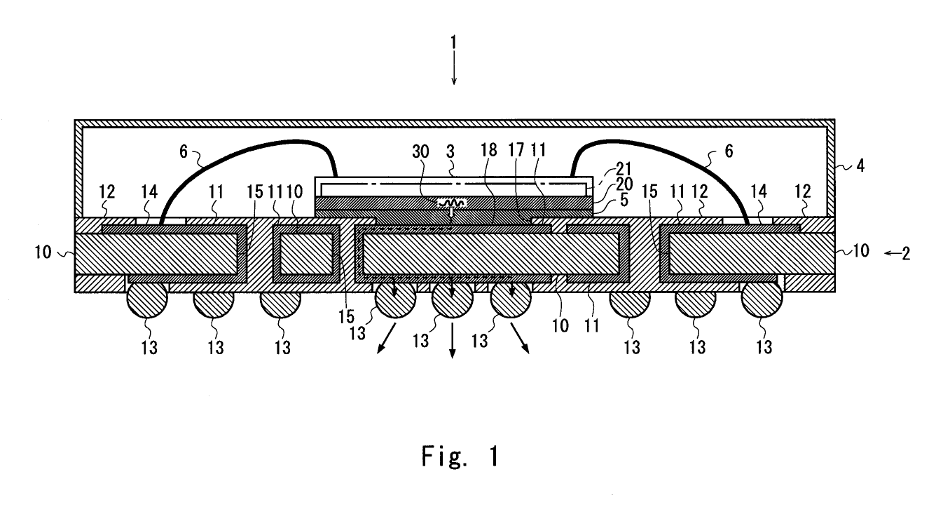

FIG. 1 shows a configuration of a semiconductor device 1 according to a first exemplary embodiment of the present invention. The semiconductor device is composed of an IC chip 3 that is mounted over a printed circuit board 2, and a package 4 such as resin that covers the printed circuit board 2. In this exemplary embodiment, a conductor 11 such as copper foil is disposed over a surface of a substrate 10. The IC chip 3 is fixed over the printed circuit board 2 coated with a solder resist 12, which is an insulating film, using AG paste 5 as an adhesive. Further, the printed circuit board 2 and the IC chip 3 are connected by a plurality of bonding wires 6 to enable transmission and reception of an electric signal.

The printed circuit board 2 is composed including the substrate 10, the conductors 11, the solder resists 12, and solder balls 13.

The substrate 10 is a plate-like member formed of phenolic resin or the like. A plurality of via openings 15 penetrating both sides of the substrate are formed in the substrate 10.

The conductor 11 is formed of copper foil etc., and mainly used as electric wiring. The conductor 11 extends from the surface where the IC chip 3 is fixed to the surface of the opposite side with the via openings 15 interposed therebetween, and is connected to the solder balls 13.

The solder resist 12 is a synthetic resin film such as epoxy system resin with insulation and photosensitivity, etc. The solder resist 12 covers the section except the electric connection points (pad and land) such as bonding points 14 between the conductors 11 and the bonding wires 6. The solder resist 12 according to this exemplary embodiment includes openings 17 in the section corresponding to the fixed surface of the IC chip 3. A part of the conductors 11 will be the exposed part 18 by the opening 17.

The solder ball 13 is an electric connection point with the external device to which the semiconductor device 1 is mounted. The solder ball 13 is connected to the conductor 11.

The IC chip 3 is composed including the substrate 20 and a functional device group 21.

The substrate 20 according to this exemplary embodiment is a plate-like member which is composed of a semiconductor, such as single-crystal silicon. The functional device group 21 which provides a predetermined function is fixed over the substrate 20. The functional device group 21 is composed of a combination of various semiconductor devices. The surface (fixed surface) of the opposite side to the surface, where the functional device group 21 of the substrate 20 is fixed, is fixed to the printed circuit board 2 by the Ag paste 5.

In FIG. 1, an elimination element 30 is shown in the substrate 20. The elimination element 30 is a representation of the unnecessary element by an image such as heat and electric noise generated by the operation of the functional device group 21.

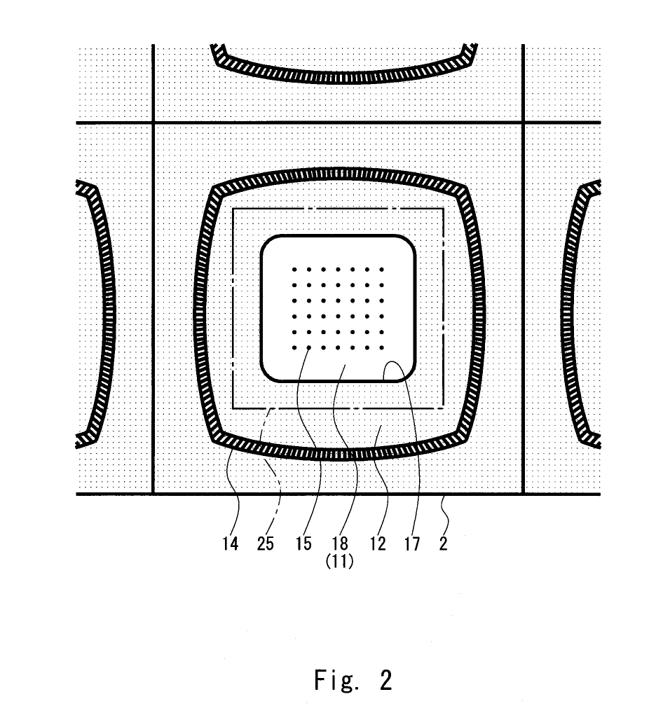

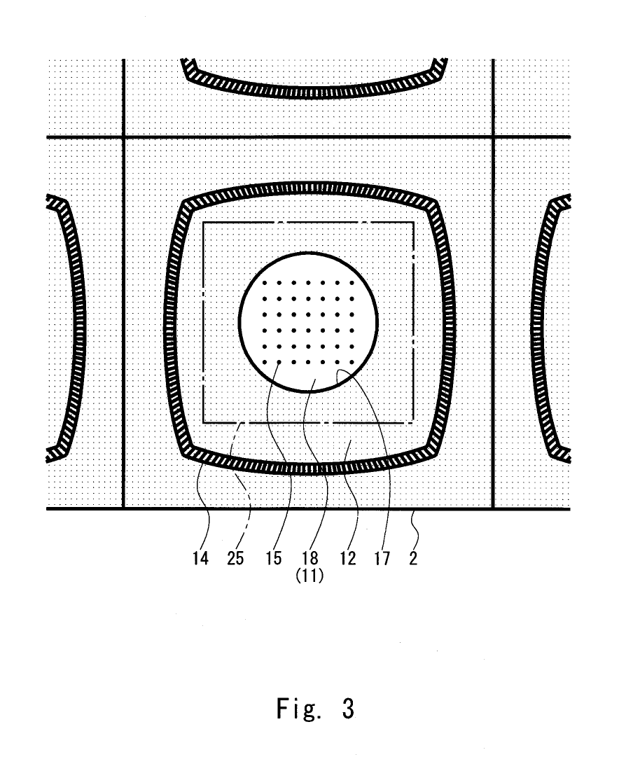

FIGS. 2 and 3 exemplify the state before mounting the IC chip 3 of the printed circuit board 2, and the shape of the opening 17. In FIGS. 2 and 3, the solder resist 12, the opening 17, the exposed part 18 (the conductor 11), the bonding point 14, the via opening 15, and a fixed place of the IC chip 3 are shown. As shown in both FIGS. 2 and 3, various shapes such as square and circle can be accepted as the shape of the opening 17. By the existence of the opening 17, a part of the conductor 11 will be exposed as the exposed part 18. In this exemplary embodiment, the conductor 11 is arranged to all the range of the opening 17 in the exposed part 18. Further, the opening 17 (the exposed part 18) exists within the range of the fixed place 25.

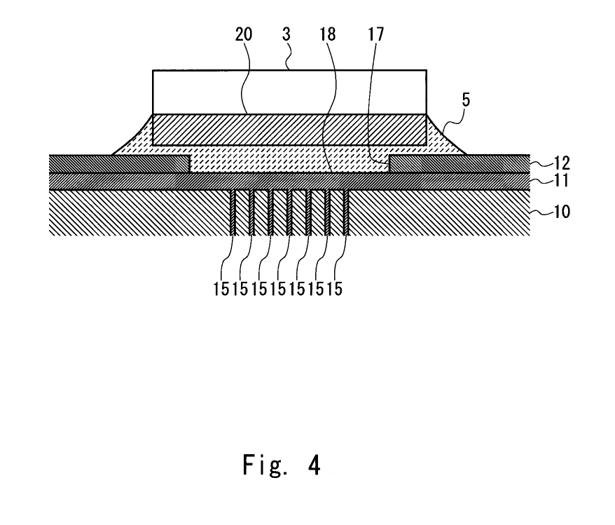

FIG. 4 schematically shows the cross-sectional configuration at the time of mounting the IC chip 3 to the fixed place 25. As shown in FIG. 4, the IC chip 3 is fixed over the solder resist 12 with the Ag paste 5 interposed therebetween. At this time, as the Ag paste 5 is filled in the opening 17, the Ag paste 5 contacts the substrate 20 of the IC chip 3, and the exposed part 18 of the conductor 11. Moreover, the conductor 11 including the exposed part 18 is connected to the solder ball 13 (see FIG. 1) through the via opening 15 formed in the substrate 10. Furthermore, the surface treatment for suppressing the generation of a Schottky barrier is performed to the fixed surface (surface in contact with the Ag paste 5) of the substrate 20. As the surface treatment, a roughing process or a process of depositing gold to the fixed surface to form an electrode are preferable.

By the above configuration, as shown in FIG. 1, the elimination element 30 in the substrate 20 generated by the operation of the functional device group 21 transmits in the order of; the substrate 20, the Ag paste 5, the exposed part 18 (the conductor 11), the via opening 15 (the conductor 11), the solder ball 13, and outside, and then the elimination element 30 is eliminated.

In this exemplary embodiment, in the exposed part 18, as the conductor 11 is arranged to all the range of the opening 17, the thermal and electrical conductivity is high, and thereby producing a high exemplary advantage of emitting the elimination element 30 to outside. Since the opening 17 (the exposed part 18) exists within the range of the fixed place 25, there is a small possibility that a crack is generated in the Ag paste 5 or the like when fixing the IC chip 3. Further, in this exemplary embodiment, the substrate 20 and the solder ball 13 are electrically connected, and the surface treatment is performed on the fixed surface of the substrate 20 for suppressing the generation of the Schottky barrier. This reduces the influence of the Schottky barrier and efficiently eliminates the Schottky barrier even in case that heat and electric noise is included in the elimination element 30.

Note that the present invention is not limited to the above exemplary embodiments but can be modified as appropriate without departing from the scope of the present invention. For example, in the abovementioned exemplary embodiment, although the printed circuit board 2 is explained to have a BGA type configuration, the present invention is not limited to this. Further, in the abovementioned exemplary embodiment, although the configuration is shown in which the substrate 20 to the solder ball 13 are not only thermally but also electrically connected, they may be only thermally connected.

While the invention has been described in terms of the exemplary embodiment, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a substrate;
an IC chip that is fixed over the substrate;
a conductor that is disposed over a surface of the substrate;
a solder resist that covers the surface of the substrate and the conductor and includes an opening that exposes the conductor to a section corresponding to a fixed surface of the IC chip; and
an adhesive that contacts an exposed part of the conductor, the exposed part being made by the opening.

2. The semiconductor device according to claim 1, wherein the conductor including the exposed part is thermally connected to a conductor for external connection through a via opening formed in the substrate, in which the conductor for external connection is disposed over a surface of an opposite side to a surface where the IC chip is fixed.

3. The semiconductor device according to claim 1, wherein in the exposed part, the conductor is arranged to an entire range of the opening.

4. The semiconductor device according to claim 1, wherein the opening exists within a range of the fixed surface.

5. The semiconductor device according to claim 1, wherein
the adhesive has conductivity, and
the fixed surface is composed of a semiconductor, and is performed with surface treatment for suppressing from generating a Schottky barrier.

6. The semiconductor device according to claim 5, wherein the surface treatment is a roughing process.

7. The semiconductor device according to claim 5, wherein the surface treatment is a process to deposit gold to the fixed surface and form an electrode.
